(19) United States
(12) Patent Application Publication
(10) Pub. No.: US 2026/0013396 A1
(43) Pub. Date: Jan. 8, 2026

(54) THERMOELECTRIC DEVICE COMPRISING NANOTUBE ARRAY AND METHOD OF MANUFACTURING THEREOF

(71) Applicant: POSTECH RESEARCH AND BUSINESS DEVELOPMENT FOUNDATION, Pohang-si (KR)

(72) Inventors: Chang Ki BAEK, Pohang-si (KR); Hyeong Seok YOO, Pohang-si (KR); Ki Yeong KIM, Pohang-si (KR)

(21) Appl. No.: 19/235,932

(22) Filed: Jun. 12, 2025

(30) Foreign Application Priority Data
Jul. 4, 2024 (KR) 10-2024-0088226

(51) Int. Cl. H10N 10/17; B82Y 15/00; H10N 10/01; H10N 10/13; H10N 10/81; H10N 10/82; H10N 10/851; H10N 10/857

(52) U.S. Cl. CPC H10N 10/17; B82Y 15/00; H10N 10/01; H10N 10/13; H10N 10/81; H10N 10/82; H10N 10/851; H10N 10/857

(57) ABSTRACT

A thermoelectric device comprising a nanotube array is provided. The thermoelectric device comprising: a substrate; a doping region in the substrate; a nanotube array; a first upper electrode; a second upper electrode; and a heat dissipation part arranged on an upper portion of the substrate and a lower portion of the substrate, wherein each of the nanotube arrays has a wall thickness of greater than or equal to 30 nm and less than or equal to 999 nm.

### CROSS-REFERENCE TO RELATED APPLICATION

This application claims priority under 35 U.S.C § 119 to Korean Patent Application No. 10-2024-0088226 filed on Jul. 4, 2024, in the Korean Intellectual Property Office, the entire contents of which are hereby incorporated by reference.

### TECHNICAL FIELD

The present disclosure relates to a thermoelectric device comprising a nanotube array and a method of manufacturing the same.

### BACKGROUND

The content described in this section simply provides background information for the present embodiment and does not constitute the prior art.

In the case of a thermoelectric device having thermoelectric performance, in order to improve thermoelectric efficiency, it is necessary to increase the Seebeck coefficient or the electrical conductivity of a thermoelectric material, or to decrease thermal conductivity. In this case, since thermal conductivity and electrical conductivity have a proportional relationship, in order to improve the performance of the thermoelectric material, it is necessary to effectively control heat transfer while maintaining electrical characteristics to reduce the thermal conductivity.

Accordingly, there has been a need for a structure of a thermoelectric device that reduces thermal conductivity while maintaining the electrical characteristics of the thermoelectric device.

### SUMMARY

An object of the present disclosure is to provide a thermoelectric device comprising a nanotube array capable of reducing thermal conductivity, and a method of manufacturing the same.

Another object of the present disclosure is to provide a thermoelectric device comprising a nanotube array, which is manufacturable by using existing semiconductor process technologies and thus suitable for mass production, and a method of manufacturing the same.

The objects of the present disclosure are not limited to the above-mentioned objects, and other objects and advantages of the present disclosure that are not mentioned will be understood by the following description and will be more clearly understood by embodiments of the present disclosure. In addition, it will be easy to see that the objects and advantages of the present disclosure may be realized by the means and combinations thereof disclosed in the claims.

According to some aspects of the disclosure, a thermoelectric device comprising a nanotube array, the thermoelectric device comprising: a substrate; a doping region in the substrate, the doping region comprising a first n-type doping region, a second n-type doping region, a first p-type doping region, and a second p-type doping region, which are arranged to be spaced apart from one another; a nanotube array comprising a first n-type nanotube array, a second n-type nanotube array, a first p-type nanotube array, and a second p-type nanotube array, each of which is arranged on a corresponding one of the first n-type doping region, the second n-type doping region, the first p-type doping region, and the second p-type doping region, wherein each of the first n-type nanotube array, the second n-type nanotube array, the first p-type nanotube array, and the second p-type nanotube array comprises a hole therein; a first upper electrode electrically connecting an upper portion of the first n-type nanotube array and an upper portion of the first p-type nanotube array; a second upper electrode electrically connecting an upper portion of the second n-type nanotube array and an upper portion of the second p-type nanotube array; and a heat dissipation part arranged on an upper portion of the substrate and a lower portion of the substrate, wherein each of the nanotube arrays has a wall thickness of greater than or equal to 30 nm and less than or equal to 999 nm.

According to some aspects, wherein a doping concentration of each of the nanotube arrays is greater than or equal to 10¹⁹ cm⁻³ and less than or equal to 10²¹ cm⁻³.

According to some aspects, wherein the first p-type doping region is arranged between the first n-type doping region and the second n-type doping region, and the second n-type doping region is arranged between the first p-type doping region and the second p-type doping region.

According to some aspects, further comprising: an upper silicide layer arranged on each of the nanotube arrays; and a lower silicide layer arranged under each of the nanotube arrays, wherein the lower silicide layer comprises: a first lower silicide layer arranged on the first n-type doping region and arranged on a portion of the substrate exposed by the hole of the first n-type nanotube array; a second lower silicide layer arranged on the first p-type doping region, on the second n-type doping region, on a portion of the substrate exposed by the hole of the first p-type nanotube array, on a portion of the substrate exposed by the hole of the second n-type nanotube array, and on another portion of the substrate between the first p-type doping region and the second n-type doping region; and a third lower silicide layer arranged on the second p-type doping region and arranged on a portion of the substrate exposed by the hole of the second p-type nanotube array.

According to some aspects, wherein each of the nanotube arrays comprises the same material as the substrate.

According to some aspects, wherein the nanotube arrays are arranged to be spaced apart from one another, and further comprising a filling layer that fills spaces between the respective nanotube arrays.

According to some aspects, wherein each of the nanotubes of the nanotube array is in any one of the following forms: a form in which the repetition of diameter increase and decrease from top to bottom is constant in magnitude of the diameter, a form in which the repetition of diameter increase and decrease from top to bottom gradually increases in magnitude of the diameter, a form in which the repetition of diameter increase and decrease from top to bottom gradually decreases in magnitude of the diameter, an hourglass shape in which the repetition of diameter increase and decrease from top to bottom gradually decreases and then increases in magnitude of the diameter so that a central portion is concave, or a bulging shape in which the repetition of diameter increase and decrease from top to bottom gradually increases and then decreases in magnitude of the diameter so that a central portion is convex.

According to some aspects, wherein a horizontal cross-section of each of nanotubes of the nanotube array is any one of a circle and a polygon, the circle and the polygon including the hole.

According to some aspects, wherein a doping material for n-type doping of the n-type of the doping region and the n-type of the nanotube array includes an atom having five valence electrons, and a doping material for p-type doping of the p-type of the doping region and the p-type of the nanotube array includes an atom having three valence electrons.

According to some aspects, wherein each of the first upper electrode, the second upper electrode, and the heat dissipation part includes at least one material selected from the group consisting of Pt, Al, Au, Cu, W, Ti, and Cr.

According to some aspects of the disclosure, a method of manufacturing a thermoelectric device comprising a nanotube array, the method comprising: patterning a ring mask pattern on a substrate; forming the nanotube array by removing a portion of the substrate using a dry etching process based on the ring mask pattern, the nanotube array having a hole therein and a wall thickness; performing a first doping process by performing a p-type doping process on a first group comprised in a first region of the substrate and a second group comprised in a second region of the substrate, and on portions of the first region and the second region of the substrate among the nanotube array, to form a first p-type doping region in the first region, to form a second p-type doping region in the second region, to form the first group as a first p-type nanotube array, and to form the second group as a second p-type nanotube array; performing a second doping process by performing an n-type doping process on a third group comprised in a third region of the substrate and a fourth group included in a fourth region of the substrate, and on portions of the third region and the fourth region of the substrate among the nanotube array, to form a first n-type doping region in the third region, to form a second n-type doping region in the fourth region, to form the third group as a first n-type nanotube array, and to form the fourth group as a second n-type nanotube array; forming a first upper electrode electrically connecting an upper portion of the first n-type nanotube array and an upper portion of the first p-type nanotube array; forming a second upper electrode electrically connecting an upper portion of the second n-type nanotube array and an upper portion of the second p-type nanotube array; and forming a heat dissipation part on a lower portion and an upper portion of the substrate, wherein the wall thickness is greater than or equal to 30 nm and less than or equal to 999 nm.

According to some aspects, wherein a doping concentration of each of the first doping process and the second doping process is greater than or equal to 10¹⁹ cm⁻³ and less than or equal to 10²¹ cm⁻³.

According to some aspects, wherein the first p-type doping region is arranged between the first n-type doping region and the second n-type doping region, and the second n-type doping region is arranged between the first p-type doping region and the second p-type doping region.

According to some aspects, the method comprising: forming an upper silicide layer on each of the nanotube arrays; forming a first lower silicide layer arranged on the first n-type doping region and arranged on a portion of the substrate exposed by the hole of the first n-type nanotube array; forming a second lower silicide layer arranged on the first p-type doping region, the second n-type doping region, a portion of the substrate exposed by the hole of the first p-type nanotube array, and a portion of the substrate exposed by the hole of the second n-type nanotube array, and further arranged on another portion of the substrate between the first p-type doping region and the second n-type doping region; and forming a third lower silicide layer arranged on the second p-type doping region and arranged on a portion of the substrate exposed by the hole of the second p-type nanotube array.

According to some aspects, further comprising: before forming the first upper electrode and the second upper electrode, forming a filling layer that fills spaces between the respective nanotube arrays and exposes at least a portion of the upper silicide layer and an upper portion of each of the nanotube arrays.

According to some aspects of the disclosure, a method of manufacturing a thermoelectric device comprising a nanotube array, the method comprising: patterning a plurality of ring mask patterns spaced apart from one another on a substrate, each of the plurality of ring mask patterns comprising a pre-hole exposing a portion of an upper surface of the substrate; forming a pre-catalyst layer on the substrate and the plurality of ring mask patterns; forming a catalyst layer by removing the plurality of ring mask patterns to expose partial regions of the substrate corresponding to the plurality of ring mask patterns; forming the nanotube array having a hole therein and a wall thickness by removing a portion of the substrate using a wet etching process based on the catalyst layer; performing a first doping process by performing a p-type doping process on a first group included in a first region of the substrate and a second group included in a second region of the substrate, and on portions of the first region and the second region of the substrate among the nanotube array, to form a first p-type doping region in the first region, to form a second p-type doping region in the second region, to form the first group as a first p-type nanotube array, and to form the second group as a second p-type nanotube array; performing a second doping process by performing an n-type doping process on a third group included in a third region of the substrate and a fourth group included in a fourth region of the substrate, and on portions of the third region and the fourth region of the substrate among the nanotube array, to form a first n-type doping region in the third region, to form a second n-type doping region in the fourth region, to form the third group as a first n-type nanotube array, and to form the fourth group as a second n-type nanotube array; forming a first upper electrode electrically connecting an upper portion of the first n-type nanotube array and an upper portion of the first p-type nanotube array; forming a second upper electrode electrically connecting an upper portion of the second n-type nanotube array and an upper portion of the second p-type nanotube array; and forming a heat dissipation part on a lower portion and an upper portion of the substrate, wherein the wall thickness is greater than or equal to 30 nm and less than or equal to 999 nm.

According to some aspects, wherein a doping concentration of each of the first doping process and the second doping process is greater than or equal to 10¹⁹ cm⁻³ and less than or equal to 10²¹ cm⁻³.

According to some aspects, wherein the first p-type doping region is arranged between the first n-type doping region and the second n-type doping region, and the second n-type doping region is arranged between the first p-type doping region and the second p-type doping region.

According to some aspects, forming an upper silicide layer on each of the nanotube arrays; forming a first lower silicide layer arranged on the first n-type doping region and arranged on a portion of the substrate exposed by the hole of the first n-type nanotube array; forming a second lower silicide layer arranged on the first p-type doping region, the second n-type doping region, a portion of the substrate exposed by the hole of the first p-type nanotube array, and a portion of the substrate exposed by the hole of the second n-type nanotube array, and further arranged on another portion of the substrate between the first p-type doping region and the second n-type doping region; and forming a third lower silicide layer arranged on the second p-type doping region and arranged on a portion of the substrate exposed by the hole of the second p-type nanotube array.

According to some aspects, further comprising: before forming the first upper electrode and the second upper electrode, forming a filling layer that fills spaces between the respective nanotube arrays and exposes at least a portion of the upper silicide layer and an upper portion of each of the nanotube arrays.

The thermoelectric device comprising a nanotube array and the method of manufacturing the same according to the present disclosure may reduce thermal conductivity by allowing the thermoelectric device to comprise the nanotube array having lower thermal conductivity than a nanowire.

In addition, the thermoelectric device comprising a nanotube array and the method of manufacturing the same according to the present disclosure may be suitable for mass production by manufacturing the nanotube array through removing a portion of a substrate using an etching process used in semiconductor processes, by utilizing existing semiconductor process technologies.

In addition to the above, the specific effects of the present disclosure will be described together with the detailed description for implementing the present disclosure.

### BRIEF DESCRIPTION OF THE DRAWINGS

FIG. 1 is a diagram for explaining a thermoelectric device comprising a nanotube array according to an embodiment of the present disclosure.

FIG. 2 is a cross-sectional view taken along line A-A of FIG. 1.

FIG. 3A is a diagram for explaining nanotubes of the thermoelectric device comprising a nanotube array according to an embodiment of the present disclosure.

FIG. 3B is a diagram for explaining a wall thickness of a nanotube.

FIG. 3C is a diagram for explaining a doping concentration of a nanotube.

FIGS. 4 and 5 are diagrams for explaining a surface of a nanotube of a thermoelectric device comprising a nanotube array according to an embodiment of the present disclosure.

FIG. 6 is an enlarged view of region M of FIG. 2.

FIG. 7 is a flowchart for explaining a method of manufacturing a thermoelectric device comprising a nanotube array according to an embodiment of the present disclosure.

FIG. 8A is a flowchart for explaining the step S100 of FIG. 7, and is a flowchart for explaining the step of forming a nanotube array according to some embodiments of the present disclosure.

FIGS. 8B and 8C are diagrams for explaining the step S101 of FIG. 8A.

FIG. 8D is a diagram for explaining the step S102 of FIG. 8A.

FIG. 9A is a flowchart for explaining the step S100 of FIG. 7, and is a flowchart for explaining a step of forming a nanotube array according to some embodiments of the present disclosure.

FIG. 9B is a diagram for explaining the step S111 of FIG. 9A.

FIG. 9C is a diagram for explaining the step S112 of FIG. 9A.

FIG. 9D is a diagram for explaining the step S113 of FIG. 9A.

FIG. 9E is a diagram for explaining the step S114 of FIG. 9A.

FIG. 10A is a flowchart for explaining the step S100 of FIG. 7, and is a flowchart for explaining a step of forming a nanotube array according to some embodiments of the present disclosure.

FIG. 10B is a diagram for explaining the step S121 of FIG. 10A.

FIG. 10C is a diagram for explaining the step S122 of FIG. 10A.

FIG. 10D is a diagram for explaining the step S123 of FIG. 10A.

FIG. 11 is a diagram for explaining the step S200 of FIG. 7.

FIGS. 12 and 13 are diagrams for explaining the step S300 of FIG. 7.

FIGS. 14, 15, and 16 are diagrams for explaining the step S400 of FIG. 7.

FIG. 17 is a diagram for explaining the step S500 of FIG. 7.

FIGS. 18 and 19 are diagrams for explaining the step S600 of FIG. 7.

FIG. 20 is a diagram for explaining the step S700 of FIG. 7.

### DETAILED DESCRIPTION OF THE PREFERRED EMBODIMENTS

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

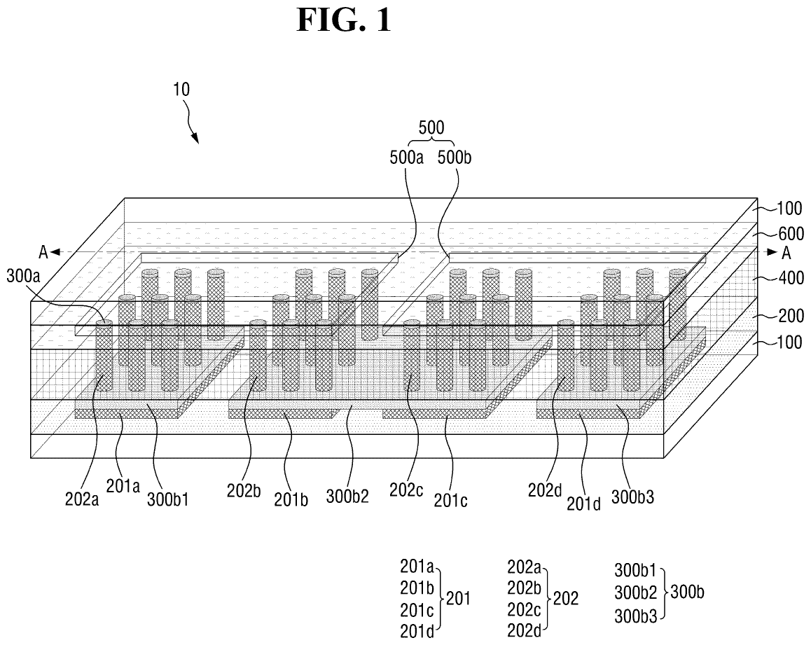

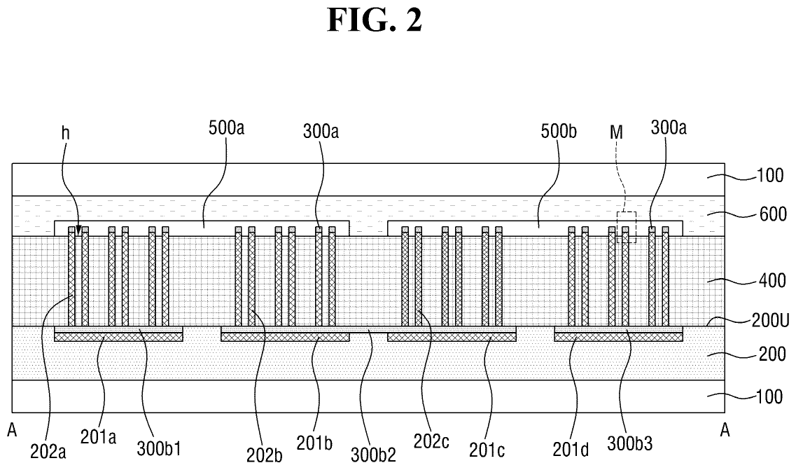

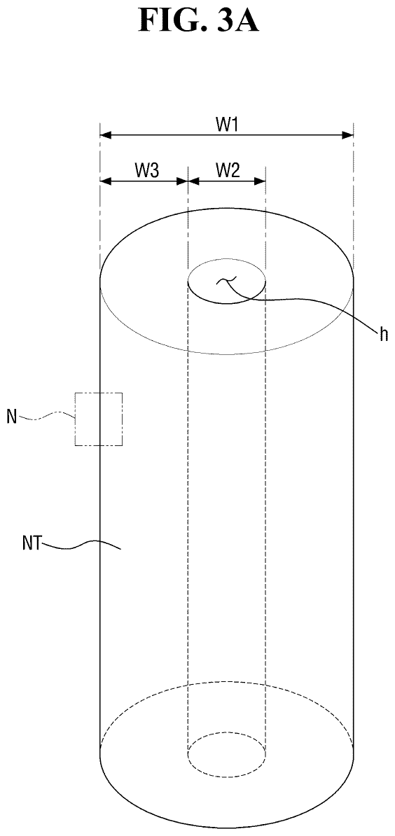

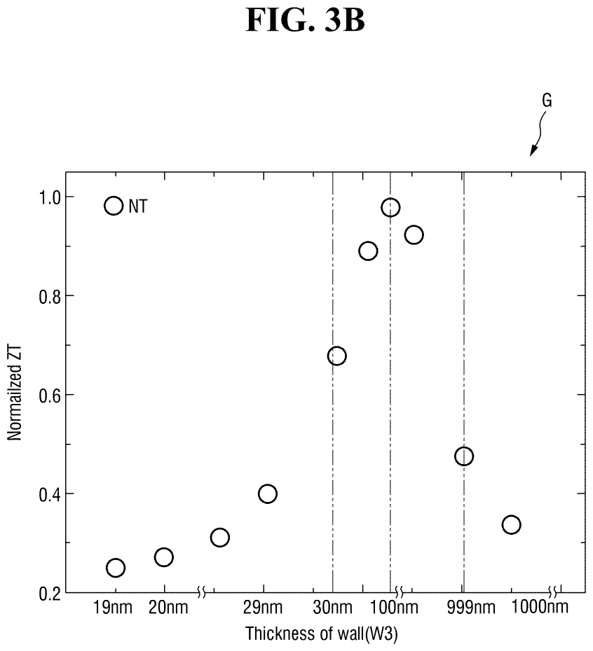

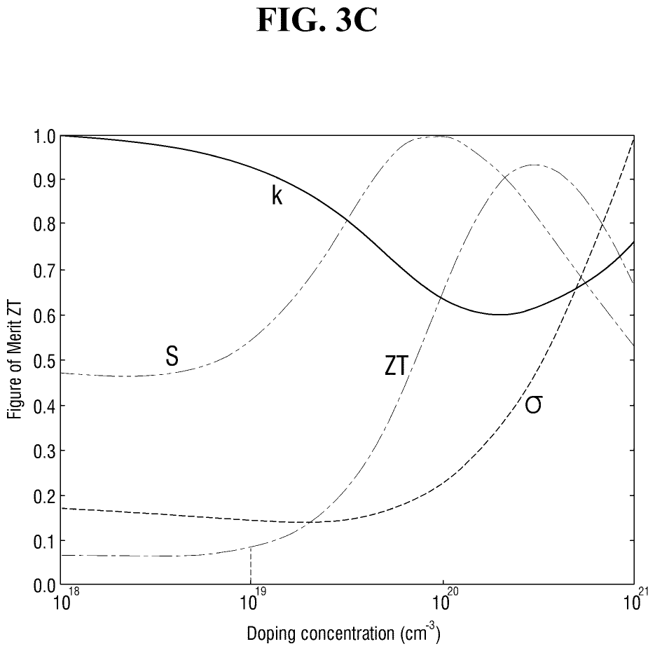

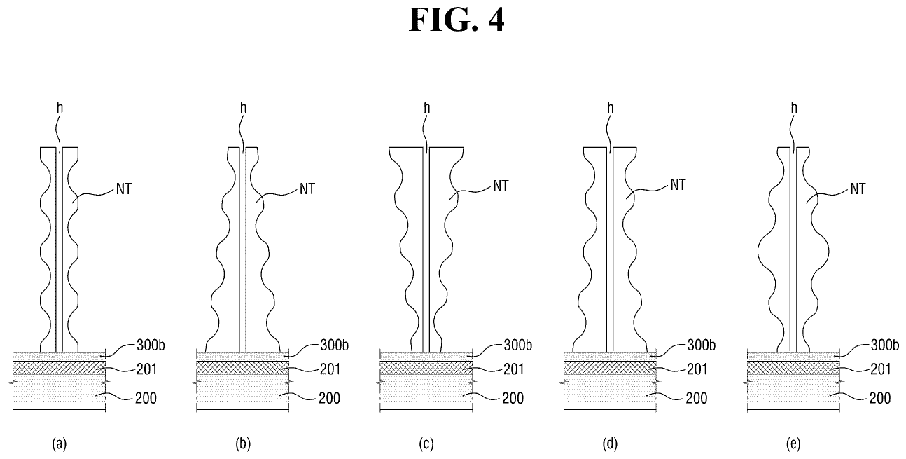

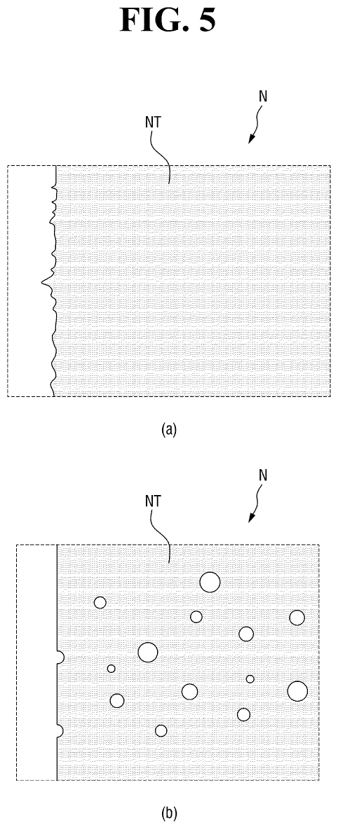

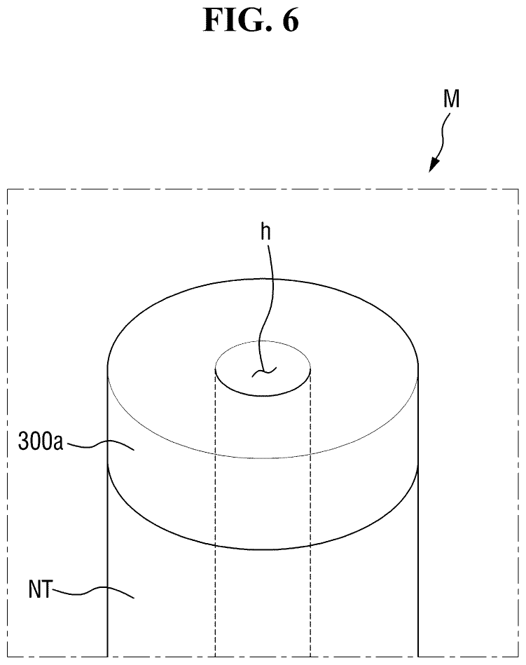

Hereinafter, a thermoelectric device comprising a nanotube array according to an embodiment of the present disclosure will be described with reference to FIG. 1, FIG. 2, FIG. 3A, FIG. 3B, FIG. 4, FIG. 5, and FIG. 6.

FIG. 1 is a diagram for explaining a thermoelectric device comprising a nanotube array according to an embodiment of the present disclosure. FIG. 2 is a cross-sectional view taken along line A-A of FIG. 1.

Referring to FIGS. 1 and 2, a thermoelectric device 10 comprising a nanotube array according to an embodiment of the present disclosure may comprise a substrate 200, a doping region 201, a nanotube array 202, an upper electrode 500, a heat emission part 100, an upper silicide layer 300a, a lower silicide layer 300b, a filling layer 400, and an insulating layer 600.

The substrate 200 may be a material usable in a thermoelectric device, and for example, may be a silicon substrate, but is not limited thereto. Alternatively, the substrate 200 may be in a form in which any one of crystalline silicon, polycrystalline silicon, amorphous silicon, a SiGe substrate, or Bi₂ Te₃ is deposited on each of a silicon substrate, a sapphire substrate, or a glass substrate.

The doping region 201 may comprise a first n-type doping region 201a, a first p-type doping region 201b, a second n-type doping region 201c, and a second p-type doping region 201d, which are spaced apart from each other in the substrate 200. The first p-type doping region 201b may be arranged between the first n-type doping region 201a and the second n-type doping region 201c. The second n-type doping region 201c may be arranged between the first p-type doping region 201b and the second p-type doping region 201d. Each of the doping regions 201 may be a region formed by doping a portion of the substrate 200. Each of the doping regions 201 may be arranged inside the substrate 200 so as to include an upper surface 200U of the substrate 200.

The first n-type doping region 201a and the second n-type doping region 201c may be regions doped with an n-type impurity. The first p-type doping region 201b and the second p-type doping region 201d may be regions doped with a p-type impurity.

The nanotube array 202 may comprise a plurality of nanotubes. The nanotube array 202 may be arranged on the doping region 201. Each of the plurality of nanotubes may be arranged to be spaced apart from one another.

The nanotube array 202 may comprise a first n-type nanotube array 202a, a first p-type nanotube array 202b, a second n-type nanotube array 202c, and a second p-type nanotube array 202d. Each of the first n-type nanotube array 202a, the first p-type nanotube array 202b, the second n-type nanotube array 202c, and the second p-type nanotube array 202d may comprise a plurality of nanotubes.

The nanotube array 202 may comprise the same material as the substrate 200. For example, when the substrate 200 comprises silicon, the nanotube array 202 may also comprise silicon.

The first n-type nanotube array 202a may be a plurality of nanotubes arranged on the first n-type doping region 201a. The first p-type nanotube array 202b may be a plurality of nanotubes arranged on the first p-type doping region 201b. The second n-type nanotube array 202c may be a plurality of nanotubes arranged on the second n-type doping region 201c. The second p-type nanotube array 202d may be a plurality of nanotubes arranged on the second p-type doping region 201d.

A doping material for the n-type of the doping region 201 and the n-type of the nanotube array 202 may include an atom having five valence electrons. For example, the doping material for n-type doping may include any one of P, As, or Sb. A doping material for the p-type of the doping region 201 and the p-type of the nanotube array 202 may include an atom having three valence electrons. For example, the doping material for p-type doping may include any one of B, BF₂, Al, or Ga.

FIG. 3A is a diagram for explaining nanotubes of the thermoelectric device comprising a nanotube array according to an embodiment of the present disclosure. FIG. 3B is a diagram for explaining a wall thickness of a nanotube. FIG. 3C is a diagram for explaining a doping concentration of a nanotube. In FIG. 3A, one nanotube is illustrated for clarity of description and illustration. For clarity of description, overlapping contents previously described are briefly mentioned or omitted.

Referring to FIGS. 1, 2, 3A, 3B, and 3C, each of the plurality of nanotubes included in the nanotube array 202 may have a structure such as a nanotube NT. The nanotube NT may include a hole h therein.

The hole h may extend through the nanotube NT from an upper surface to a lower surface of the nanotube NT. Since the hole h exists inside the nanotube NT, the surface-to-volume ratio increases, resulting in an increase in phonon scattering effects occurring on the surface of the nanotube NT, and phonon movement inside the nanotube NT is restricted, thereby significantly reducing thermal conductivity. In addition, when surface roughness of the nanotube NT increases, additional diffusive scattering and back scattering may occur, thereby exceeding the Casimir limit, which is a thermal conductivity reduction limit due to phonon scattering, and thermal conductivity may be significantly reduced. Furthermore, since the hole h exists inside the nanotube NT, a relative loss of electrical conductivity may not occur, and thus the efficiency of the thermoelectric device may be improved.

The nanotube NT may have a wall thickness W3 of 30 nm or more and 999 nm or less. The wall thickness W3 may be a difference between an outer diameter W1 and an inner diameter W2 of the nanotube NT.

A graph G in FIG. 3B is a graph related to thermal conductivity, electrical conductivity, and the Seebeck coefficient. ZT is a dimensionless figure of merit that determines the thermoelectric efficiency of a thermoelectric device, and is determined by the following Equation 1.

$$Z T = {S}^{2} σ T / k \qquad [ Equation 1 ]$$

In Equation 1, S represents the Seebeck coefficient, σ represents electrical conductivity, k represents thermal conductivity, and T represents absolute temperature, wherein the Seebeck coefficient refers to a value obtained by dividing an electromotive force generated in the thermoelectric device by a temperature difference.

In the graph G, the x-axis represents the wall thickness of the nanotube NT (unit: nm), and the y-axis represents the generalized figure of merit ZT. The wall thickness W3 of the nanotube NT was experimentally increased or decreased in units of 1 nm. As the wall thickness W3 of the nanotube NT decreases, the thermal conductivity decreases, but the generalized figure of merit ZT may also decrease. For example, when the wall thickness W3 of the nanotube NT is 20 nm, thermal conductivity is low, but electrical conductivity is also reduced, and thus a generalized figure of merit ZT of the nanotube NT when the wall thickness W3 is 20 nm is significantly lower than that when the wall thickness W3 is 30 nm.

When the wall thickness W3 of the nanotube NT is 29 nm, the generalized figure of merit ZT of the nanotube NT is about 0.4, whereas when the wall thickness W3 is 30 nm, the generalized figure of merit ZT is 0.7, showing a significant difference. In addition, when the wall thickness W3 of the nanotube NT is 1000 nm, the generalized figure of merit ZT of the nanotube NT is about 0.3, whereas when the wall thickness W3 is 999 nm, it is about 0.5, showing a significant difference. From the perspective of the generalized figure of merit ZT, it can be seen that when the wall thickness W3 of the nanotube NT is in the range of 30 nm or more and 999 nm or less, the generalized figure of merit ZT is significantly higher than in other thickness ranges.

Accordingly, when the wall thickness W3 of the nanotube NT is in the range of 30 nm or more and 999 nm or less, it is possible to reduce only the thermal conductivity while maintaining electrical conductivity.

Preferably, when the wall thickness W3 of the nanotube NT is 100 nm, the generalized figure of merit ZT may be the highest.

Meanwhile, the inclusion of a nanotube in a thermoelectric device instead of a nanowire may also be related to the figure of merit. For example, when the wall thickness W3 of the nanotube NT is 100 nm, and the outer diameter of the nanotube NT is equal to that of a nanowire, comparing the generalized figures of merit of the nanotube NT and the nanowire shows that the figure of merit of the nanotube NT is higher than that of the nanowire. In other words, when the diameter is the same, the figure of merit of the nanotube is higher than that of the nanowire, and thus even a small hole formed in the nanowire may significantly lower thermal conductivity. The nanotube array 202 may have a higher aspect ratio than a general nanowire structure, and may improve thermoelectric generation performance per unit area and the stability of a thermoelectric element by maintaining high thermoelectric performance and a stable temperature difference.

A horizontal cross-section of the nanotube NT may be circular and include the hole h. However, the present disclosure is not limited thereto, and a horizontal cross-section of the nanotube NT may also be a polygon including the hole h.

A doping concentration of each of the plurality of nanotubes included in the nanotube array 202 may be greater than or equal to 10¹⁹ cm⁻³ and less than or equal to 10²¹ cm⁻³.

A graph ZT in FIG. 3C is a graph ZT related to thermal conductivity, electrical conductivity, and the Seebeck coefficient, in which the x-axis represents doping concentration (unit: cm⁻³), and the y-axis represents a figure of merit ZT.

It is preferable that each of the plurality of nanotubes included in the nanotube array 202 has a doping concentration in a range of 10¹⁹ cm⁻³ or more and 10²¹ cm⁻³ or less, where the ZT value is the highest. Referring to the graph ZT, it can be seen that ZT increases from 10¹⁹ cm⁻³ and becomes large in the range of 10¹⁹ cm⁻³ or more and 10²¹ cm⁻³ or less.

FIGS. 4 and 5 are diagrams for explaining a surface of a nanotube of a thermoelectric device comprising a nanotube array according to an embodiment of the present disclosure. FIG. 5 is an enlarged view of region N of FIG. 3A. For clarity of description, overlapping contents previously described are briefly mentioned or omitted.

Referring to FIGS. 1, 2, 3A, and 4, a cross-sectional shape of the nanotube NT may have various vertical cross-sections according to changes in etching process conditions during the manufacture of the thermoelectric device.

Each of the nanotubes (NT) of the nanotube array (202) may have any one of the following forms: (a) a form in which the repetition of diameter increase and decrease from top to bottom is constant in the magnitude of the diameter, (b) a form in which the repetition of diameter increase and decrease from top to bottom gradually increases in the magnitude of the diameter, (c) a form in which the repetition of diameter increase and decrease from top to bottom gradually decreases in the magnitude of the diameter, (d) an hourglass shape in which the repetition of diameter increase and decrease from top to bottom gradually decreases and then increases in the magnitude of the diameter so that a central portion is concave, or (e) a bulging shape in which the repetition of diameter increase and decrease from top to bottom gradually increases and then decreases in the magnitude of the diameter so that the central portion is convex.

However, the present disclosure is not limited thereto, and each of the nanotubes NT of the nanotube array 202 may be in any one of the following forms: a form in which the diameter increases from top to bottom; a form in which the diameter decreases from top to bottom; a jar shape in which the diameter gradually increases from top to bottom and then decreases to form a convex central portion; or an hourglass shape in which the diameter gradually decreases from top to bottom and then increases to form a concave central portion.

Referring to FIGS. 1, 2, 3A, and 5, a vertical cross-sectional shape of each nanotube NT of the nanotube array 202 may be in any one of the following forms: (a) a form in which a surface of the nanotube NT is irregularly rough; or (b) a form in which the surface of the nanotube NT includes voids.

FIG. 6 is an enlarged view of region M of FIG. 2. For clarity of illustration, components other than the nanotube NT and the upper silicide layer 300a are omitted, and a perspective view is illustrated.

Referring to FIGS. 1, 2, and 6, a thermoelectric device 10 comprising a nanotube array according to an embodiment of the present disclosure may comprise an upper silicide layer 300a and a lower silicide layer 300b. The upper silicide layer 300a and the lower silicide layer 300b lower thermal conductivity by interfering with phonon transmission between silicon and silicide at an interface. In addition, the upper silicide layer 300a and the lower silicide layer 300b serve to filter the flow of electrons or holes by forming a Schottky barrier at the interface. Among electrons and holes generated by thermal energy, when they have energy smaller than the Schottky barrier, the electrons and holes accumulate near the barrier, and when a sufficient number of electrons or holes are accumulated, a large number of electrons or holes may cross the barrier due to specific electrons or holes, thereby increasing the Seebeck voltage at both ends of the nanowire.

The upper silicide layer 300a may be arranged on the top of each nanotube of the nanotube array 202. The upper silicide layer 300a may be arranged on a top portion of the nanotube NT. The hole h may penetrate the upper silicide layer 300a.

The lower silicide layer 300b may be arranged on a lower portion of each nanotube of the nanotube array 202. The lower silicide layer 300b may comprise a first lower silicide layer 300b1, a second lower silicide layer 300b2, and a third lower silicide layer 300b3.

The second lower silicide layer 300b2 may be arranged between the first lower silicide layer 300b1 and the third lower silicide layer 300b3.

The first lower silicide layer 300b1 may be arranged on the first n-type doping region 201a, and may be arranged on a portion of the substrate 200 that is exposed by the hole h of the first n-type nanotube array 202a. The first lower silicide layer 300b1 may be arranged to surround the first n-type nanotube array 202a. The first lower silicide layer 300b1 may be arranged as a part of the first n-type doping region 201a and may be located inside the first n-type doping region 201a.

The second lower silicide layer 300b2 may be arranged on the first p-type doping region 201b, on the second n-type doping region 201c, on portions of the substrate 200 exposed by the holes h of the first p-type nanotube array 202b and the second n-type nanotube array 202c, and on another portion of the substrate 200 between the first p-type doping region 201b and the second n-type doping region 201c. The second lower silicide layer 300b2 may extend from the first p-type doping region 201b to the second n-type doping region 201c. The second lower silicide layer 300b2 may be arranged between the first p-type nanotube array 202b and between the second n-type nanotube array 202c, and may be arranged to surround each of the first p-type nanotube array 202b and the second n-type nanotube array 202c. In the second lower silicide layer 300b2, A portion of the second lower silicide layer 300b2 arranged on the first p-type doping region 201b and another portion of the second lower silicide layer 300b2 arranged on the second n-type doping region 201c may be connected to each other through a remaining portion of the second lower silicide layer 300b2. The remaining portion of the second lower silicide layer 300b2 may be a partial region of the substrate 200 between the second p-type doping region 201d and the first n-type doping region 201a. The second lower silicide layer 300b2 may be arranged as a partial region of each of the first p-type doping region 201b, the substrate 200, and the second n-type doping region 201c, and may be arranged inside each of the first p-type doping region 201b, the substrate 200, and the second n-type doping region 201c.

The third lower silicide layer 300b3 may be arranged on the second p-type doping region 201d, and may be arranged on a portion of the substrate 200 that is exposed by the hole h of the second p-type nanotube array 202d. The third lower silicide layer 300b3 may be arranged to surround the second p-type nanotube array 202d. The third lower silicide layer 300b3 may be arranged as a part of the second p-type doping region 201d and may be arranged inside the second p-type doping region 201d.

Referring again to FIGS. 1 and 2, the thermoelectric device 10 comprising a nanotube array according to an embodiment of the present disclosure may comprise a filling layer 400 arranged on the substrate 200. The filling layer 400 may be arranged to fill spaces between each of the plurality of nanotubes included in the nanotube array 202. The filling layer 400 may be arranged to expose an upper portion of the nanotube array 202. The filling layer 400 may be arranged to expose the upper silicide layer 300a. The filling layer 400 may be arranged between the first upper electrode 500a and the lower silicide layer 300b, and between the second upper electrode 500b and the lower silicide layer 300b.

Due to the filling layer 400, each of the plurality of nanotubes included in the nanotube array 202 may be able to withstand external impact. The filling layer 400 may have lower thermal conductivity than the nanotube array 202. Because the filling layer 400 has low thermal conductivity, thermal energy passing through the nanotube array 202 may smoothly move from a lower end to an upper end of each of the plurality of nanotubes included in the nanotube array 202 without flowing through the filling layer 400. In addition, due to the filling layer 400, the nanotube array 202 may be stably supported so as not to be corroded by physical impact or chemical contamination. Furthermore, due to the filling layer 400, the upper electrode 500 and the lower silicide layer 300b may be electrically and thermally insulated.

The filling layer 400 may include any one of polyimide, SOG, BPDG, SiO₂, Si₃ N₄, or SiN.

The thermoelectric device 10 comprising a nanotube array according to an embodiment of the present disclosure may comprise the first upper electrode 500a and the second upper electrode 500b.

The first upper electrode 500a may electrically connect the upper portion of the first n-type nanotube array 202a and the upper portion of the first p-type nanotube array 202b. The first upper electrode 500a may be arranged to cover an upper portion of the first n-type nanotube array 202a and an upper portion of the first p-type nanotube array 202b exposed by the filling layer 400. The first upper electrode 500a may be arranged to cover the upper silicide layer 300a arranged on each of the upper portion of the first n-type nanotube array 202a and the upper portion of the first p-type nanotube array 202b.

The second upper electrode 500b may be arranged to be spaced apart from the first upper electrode 500a. The second upper electrode 500b may electrically connect an upper portion of the second n-type nanotube array 202c and an upper portion of the second p-type nanotube array 202d. The second upper electrode 500b may be arranged to cover the upper portion of the second n-type nanotube array 202c and the upper portion of the second p-type nanotube array 202d exposed by the filling layer 400. The second upper electrode 500b may be arranged to cover the upper silicide layer 300a arranged on each of the upper portion of the second n-type nanotube array 202c and the upper portion of the second p-type nanotube array 202d.

The first upper electrode 500a and the second upper electrode 500b may allow an upper portion of the doped nanotube array 202 to be in contact with a low-temperature or high-temperature heat source, and may serve as a path through which a current generated by thermoelectric conversion flows. Accordingly, the first upper electrode 500a and the second upper electrode 500b may include a metal having high thermal conductivity. For example, the first upper electrode 500a and the second upper electrode 500b may include at least one material selected from among Pt, Al, Au, Cu, W, Ti, and Cr.

The insulating layer 600 may be arranged on the filling layer 400. The insulating layer 600 may be arranged to cover an upper surface and a side surface of each of the first upper electrode 500a and the second upper electrode 500b. Due to the insulating layer 600, physical damage and contamination of each of the first upper electrode 500a and the second upper electrode 500b may be prevented, and an insulating purpose for preventing an electrical short caused by an external factor may be achieved. The insulating layer 600 may include a material that can effectively conduct heat but electrically insulate. For example, the insulating layer 600 may include any one of AlN, Al₂ O₃, SOG, SiO₂, Si₃ N₄, or SiN.

The heat emission part 100 may be arranged on a lower portion and an upper portion of the substrate 200. The heat emission part 100 may be arranged on the lower portion of the substrate 200 and may also be arranged on the insulating layer 600. The heat emission part 100 may include a material having high thermal conductivity. For example, the heat emission part 100 may include a material having high thermal conductivity such as diamond, AlN, or Al₂ O₃. The heat emission part 100 may include at least one material selected from among Pt, Al, Au, Cu, W, Ti, and Cr.

The thermoelectric device 10 comprising a nanotube array according to an embodiment of the present disclosure may maintain low thermal conductivity by including the nanotube array. In addition, the thermoelectric device 10 comprising a nanotube array according to an embodiment of the present disclosure may maintain low thermal conductivity by including a nanotube array having a wall thickness greater than or equal to 30 nm and less than or equal to 999 nm.

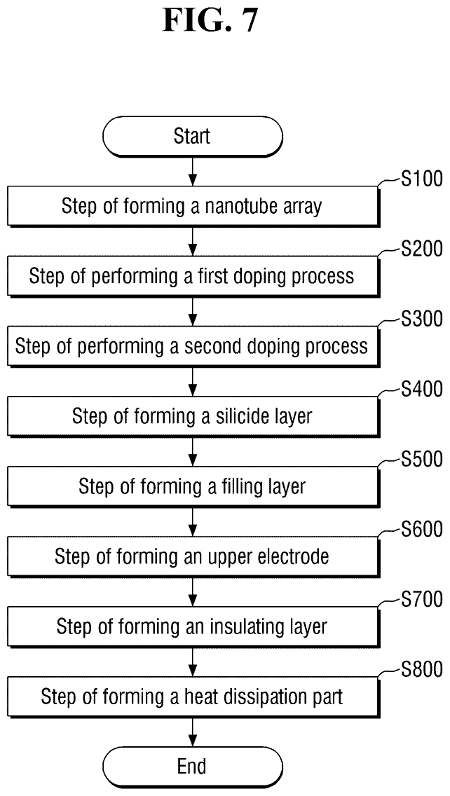

Hereinafter, a method of manufacturing a thermoelectric device comprising a nanotube array according to an embodiment of the present disclosure will be described with reference to FIGS. 7 to 20. For clarity of description, overlapping content with the above description is briefly mentioned or omitted.

FIG. 7 is a flowchart for explaining a method of manufacturing a thermoelectric device comprising a nanotube array according to an embodiment of the present disclosure.

Referring to FIG. 7, the method of manufacturing a thermoelectric device comprising a nanotube array according to an embodiment of the present disclosure may include a step S100 of forming the nanotube array. The nanotube array may be formed by removing a portion of a substrate through an etching process used in a semiconductor device manufacturing process.

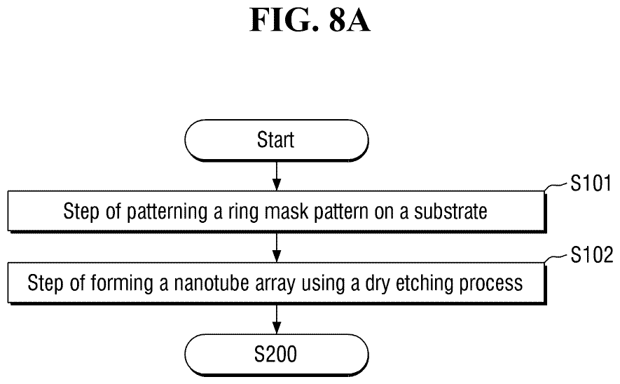

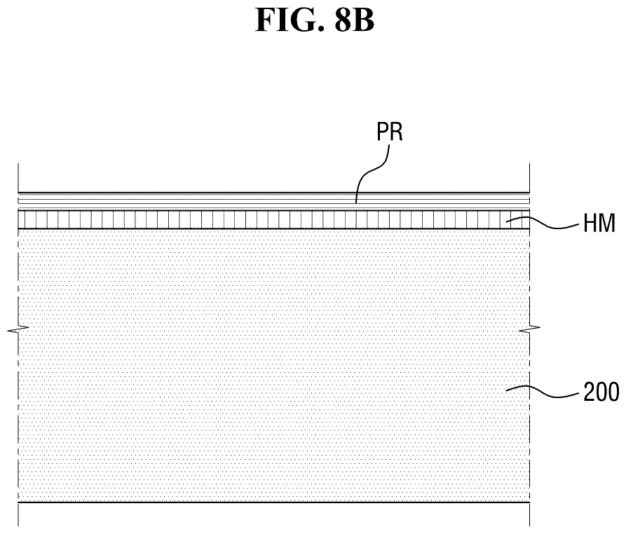

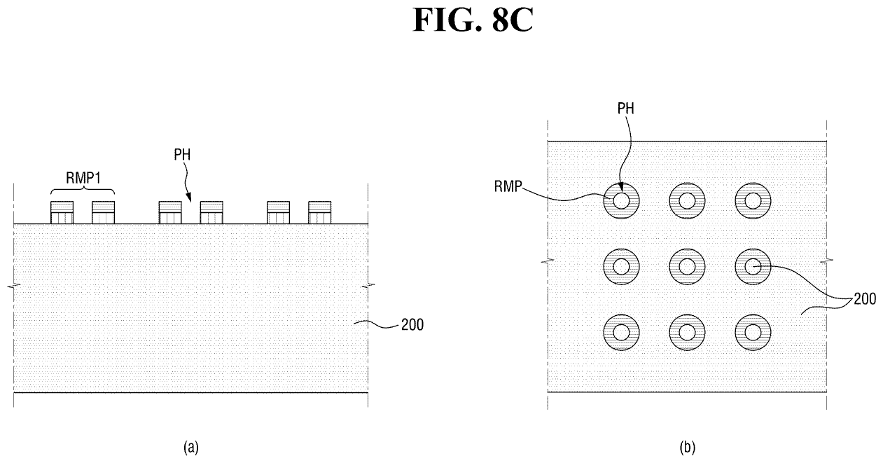

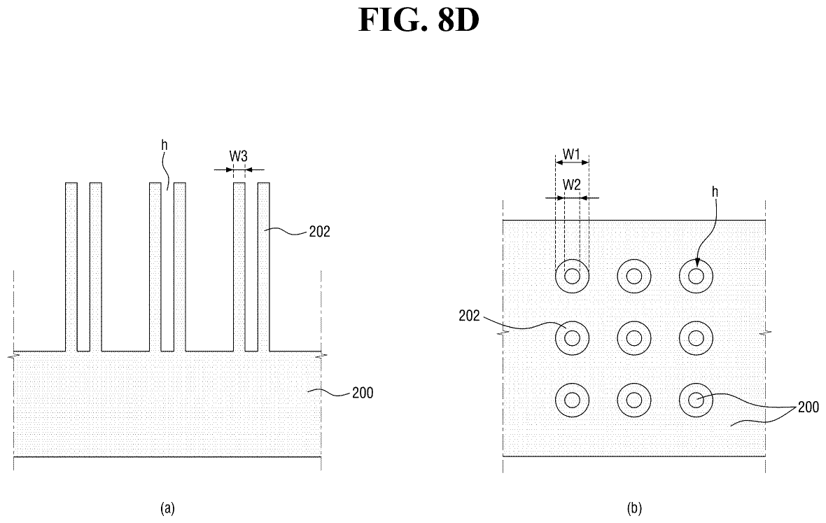

FIG. 8A is a flowchart for explaining the step S100 of FIG. 7, and is a flowchart for explaining the step of forming a nanotube array according to some embodiments of the present disclosure. FIGS. 8B and 8C are diagrams for explaining the step S101 of FIG. 8A. FIG. 8D is a diagram for explaining the step S102 of FIG. 8A.

Referring to FIGS. 7 and 8A, the step S100 of forming the nanotube array in the method of manufacturing a thermoelectric device comprising a nanotube array according to an embodiment of the present disclosure may include a step S101 of patterning a ring mask pattern (i.e., a first ring mask pattern) on a substrate, and a step S102 of forming the nanotube array using a dry etching process. In some embodiments, the nanotube array may be formed through a single etching process by using a ring mask pattern.

Referring to FIGS. 8A and 8B, in order to pattern a plurality of first ring mask patterns, a hard mask layer HM and a photoresist layer PR may first be formed on the substrate 200. The photoresist layer PR may be formed on the hard mask layer HM.

Referring to FIGS. 8A and 8C, a plurality of first ring mask patterns RMP1, in which the hard mask layer HM and the photoresist layer PR are patterned, may be formed on the substrate 200. Each of the plurality of first ring mask patterns RMP1 may include a pre-hole PH therein. The pre-hole PH may expose the substrate 200. Each of the plurality of first ring mask patterns RMP1 may be arranged on the substrate 200 to be spaced apart from one another.

In the drawings, the plurality of first ring mask patterns RMP1 are illustrated as being circular, but the present disclosure is not limited thereto. As long as a hole is included therein, the pattern may be either circular or polygonal.

Referring to FIGS. 8A and 8D, based on the plurality of first ring mask patterns RMP1, a portion of the substrate 200 may be removed using a dry etching process, so that the nanotube array 202 having a wall thickness W3 and including a hole h therein may be formed. Here, the nanotube array 202 may be a nanotube array before a doping process is performed.

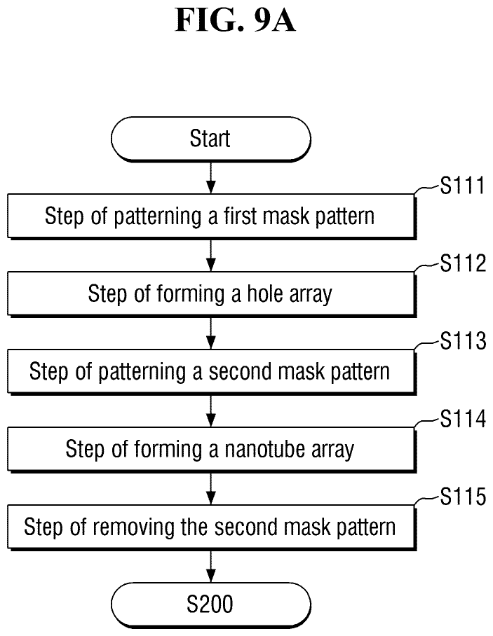

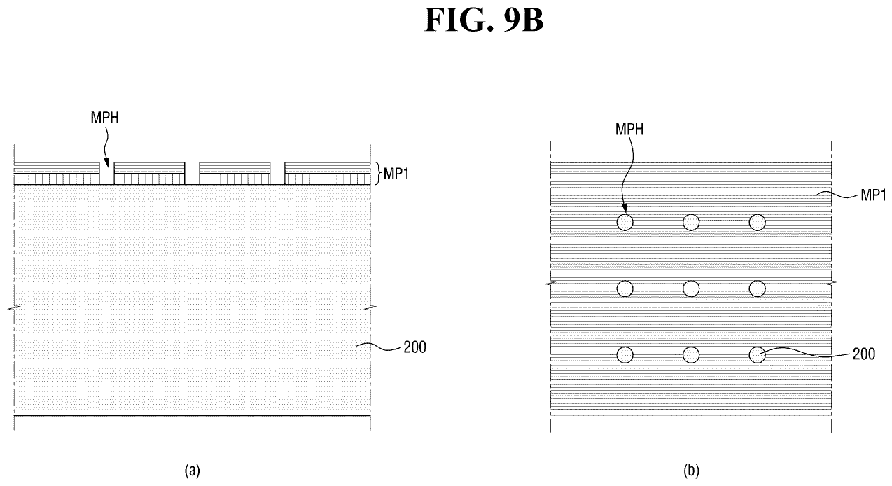

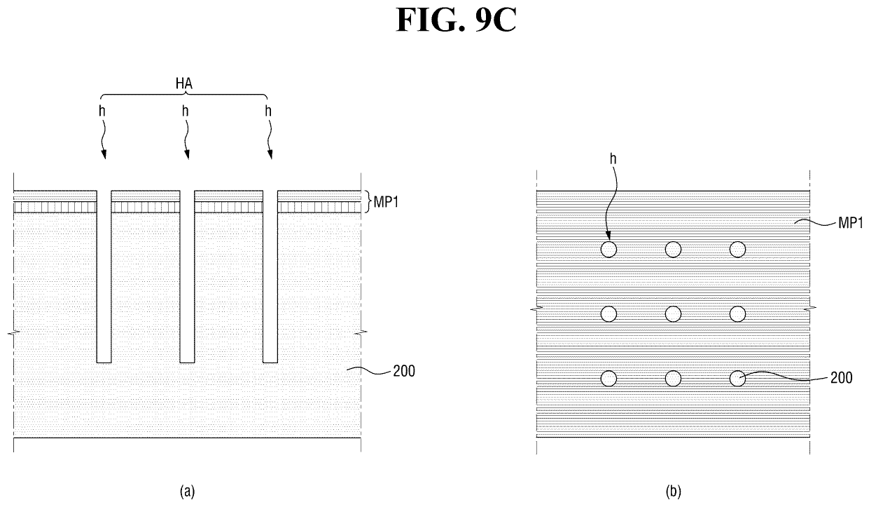

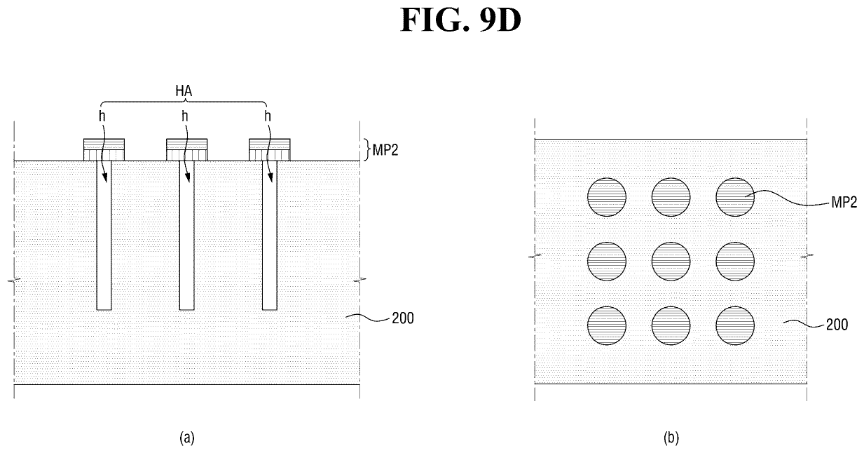

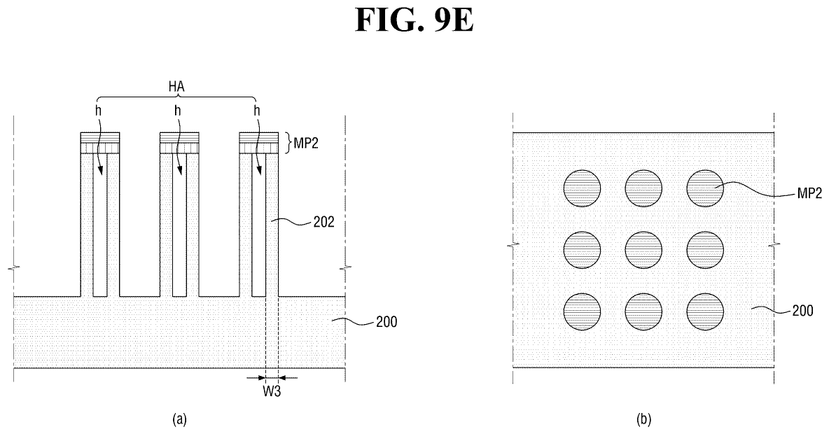

FIG. 9A is a flowchart for explaining the step S100 of FIG. 7, and is a flowchart for explaining a step of forming a nanotube array according to some embodiments of the present disclosure. FIG. 9B is a diagram for explaining the step S111 of FIG. 9A. FIG. 9C is a diagram for explaining the step S112 of FIG. 9A. FIG. 9D is a diagram for explaining the step S113 of FIG. 9A. FIG. 9E is a diagram for explaining the step S114 of FIG. 9A.

Referring to FIGS. 7 and 9A, the step S100 of forming the nanotube array in the method of manufacturing a thermoelectric device comprising a nanotube array according to an embodiment of the present disclosure may include a step S111 of patterning a first mask pattern, a step S112 of forming a hole array, a step S113 of patterning a second mask pattern, a step S114 of forming the nanotube array, and a step S115 of removing the second mask pattern.

In some embodiments, the nanotube array may be formed by first forming holes (i.e., interiors of the nanotube array) and then forming outer walls, such that the etched depths of the inner and outer portions are the same.

Referring to FIGS. 9A and 9B, the first mask pattern MP1 may be patterned on the substrate 200 (S111). First, in order to pattern the first mask pattern MP1, a hard mask layer may be formed on the substrate 200. After the hard mask layer is formed, a photoresist layer may be formed on the hard mask layer. After a pre-first mask pattern is formed in the hard mask layer, the same pattern as the pre-first mask pattern may be transferred to the photoresist layer, so that the first mask pattern MP1 may be formed. The first mask pattern MP1 may include a plurality of mask holes MPH. By the plurality of mask holes MPH, a portion of the substrate 200 may be exposed. The first mask pattern MP1 may include the plurality of mask holes MPH that are spaced apart from one another.

Referring to FIGS. 9A and 9C, based on the first mask pattern MP1, a portion of the substrate 200 may be removed using an etching process (e.g., a dry etching process), so that a hole array HA corresponding to the plurality of mask holes MPH may be formed inside the substrate 200 (S112). The hole array HA may include a plurality of holes h corresponding to the plurality of mask holes MPH of the first mask pattern MP1. Each of the plurality of holes h may be formed to be spaced apart from one another. Each of the plurality of holes h may extend from an upper surface of the substrate 200 toward a lower surface thereof to a part of the substrate 200, and may not penetrate the substrate 200.

Referring to FIGS. 9A and 9D, a second mask pattern MP2 covering an upper surface of each of the plurality of holes h included in the hole array HA may be patterned (S113). For example, a hard mask may be formed on the substrate 200 in which the hole array HA is formed. A photoresist layer may be formed on the hard mask. After the photoresist layer is patterned so that it remains at positions corresponding to the hole array HA, the hard mask layer may be etched to form the same pattern as the patterned photoresist layer. In the drawings, the second mask pattern MP2 is illustrated as being circular, but the present disclosure is not limited thereto. For example, the second mask pattern MP2 may be any one of a circle or a polygon. The shape of a horizontal cross-section of a nanotube may be determined by the second mask pattern MP2.

Referring to FIGS. 9A, 9E, and 8D, based on the second mask pattern MP2, a portion of the substrate 200 may be removed using an etching process (e.g., a dry etching process), so that a nanotube array 202 having a wall thickness W3 and including the hole array HA therein may be formed (S114). The second mask pattern MP2 may be removed (S115). Each of the nanotube arrays 202 may include a hole h therein.

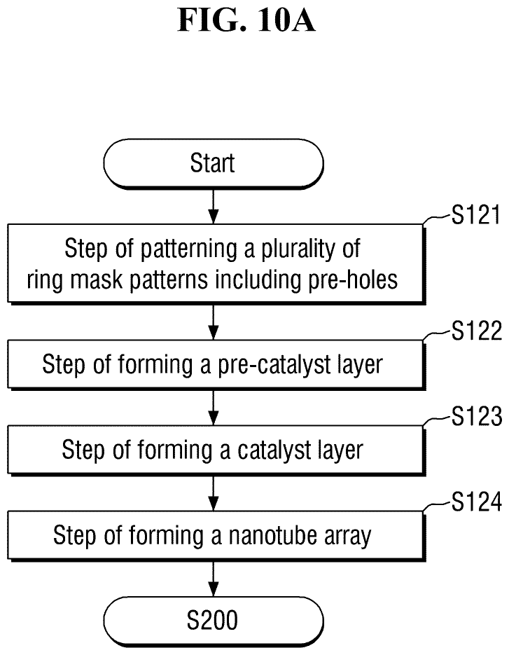

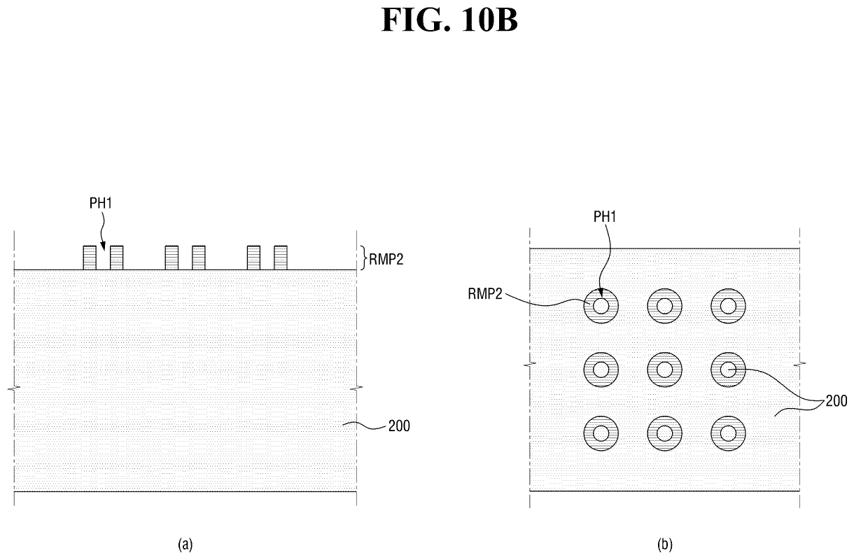

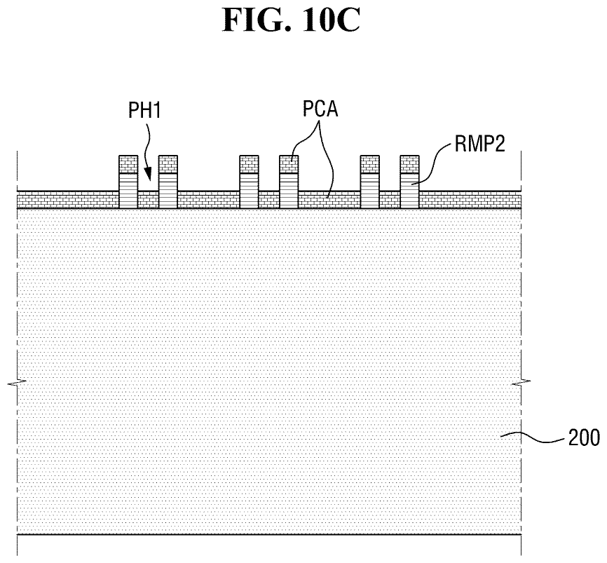

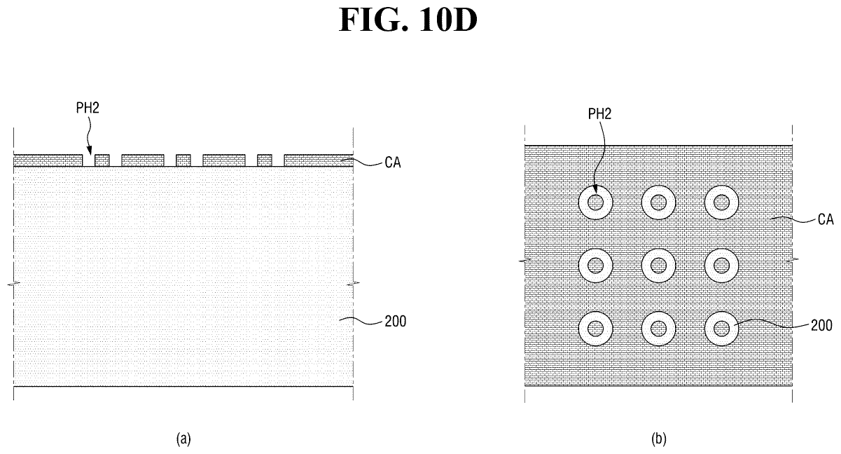

FIG. 10A is a flowchart for explaining the step S100 of FIG. 7, and is a flowchart for explaining a step of forming a nanotube array according to some embodiments of the present disclosure. FIG. 10B is a diagram for explaining the step S121 of FIG. 10A. FIG. 10C is a diagram for explaining the step S122 of FIG. 10A. FIG. 10D is a diagram for explaining the step S123 of FIG. 10A.

Referring to FIGS. 7 and 10A, the step S100 of forming the nanotube array in the method of manufacturing a thermoelectric device comprising a nanotube array according to an embodiment of the present disclosure may include a step S121 of patterning a plurality of ring mask patterns including pre-holes, a step S122 of forming a pre-catalyst layer, a step S123 of forming a catalyst layer, and a step S124 of forming the nanotube array.

Referring to FIGS. 10A and 10B, a plurality of second ring mask patterns RMP2 spaced apart from one another may be formed on the substrate 200 (S121). To form the plurality of second ring mask patterns RMP2, a photoresist layer may first be formed on the substrate 200. The photoresist layer may be patterned so that the plurality of second ring mask patterns RMP2 may be formed. The plurality of second ring mask patterns RMP2 may include a first pre-hole PH1 that exposes a portion of an upper surface of the substrate 200. Each of the plurality of second ring mask patterns RMP2 may be arranged on the substrate 200 to be spaced apart from one another.

In the drawings, the plurality of second ring mask patterns RMP2 are illustrated as being circular, but the present disclosure is not limited thereto. As long as a hole is included therein, the pattern may be either circular or polygonal.

Referring to FIGS. 10A and 10C, a pre-catalyst layer PCA may be formed on the substrate 200 and the plurality of second ring mask patterns RMP2 (S122). The pre-catalyst layer PCA may not fill all of the first pre-holes PH1.

Referring to FIGS. 10A, 10D, and 8D, the plurality of second ring mask patterns RMP2 may be removed, so that a catalyst layer CA exposing partial regions of the substrate 200 corresponding to the plurality of second ring mask patterns RMP2 may be formed (S123). Second pre-holes PH2 may be formed at locations where the plurality of second ring mask patterns RMP2 are removed. The catalyst layer CA may include the second pre-holes PH2. As the second pre-holes PH2 are formed at locations where the plurality of second ring mask patterns RMP2 are removed, the catalyst layer CA may expose partial regions of the substrate 200 through the second pre-holes PH2. The catalyst layer CA may include a metal material.

Based on the catalyst layer CA, a portion of the substrate 200 may be removed using a wet etching process, so that a nanotube array 202 having a wall thickness W3 and including a hole h therein may be formed. For example, through the wet etching process, a portion of the substrate 200 corresponding to the second pre-hole PH2 of the catalyst layer CA may remain, and a remaining portion of the substrate 200 covered by the catalyst layer CA may be removed, so that the nanotube array 202 may be formed. The second pre-hole PH2 may become the hole h included inside the nanotube array 202.

After the nanotube array 202 is formed, the remaining catalyst layer CA may be removed.

In some embodiments, the wet etching process may be performed in a different order. For example, the nanotube array may be formed through a wet etching process by first depositing the catalyst layer on the substrate, and then selectively removing only the regions of the catalyst layer corresponding to the plurality of second ring mask patterns using a photoresist layer.

Referring again to FIG. 7, the method of manufacturing a thermoelectric device comprising a nanotube array according to an embodiment of the present disclosure may include a step S200 of performing a first doping process and a step S300 of performing a second doping process after forming the nanotube array (S100). The first doping process and the second doping process may be performed in reverse order.

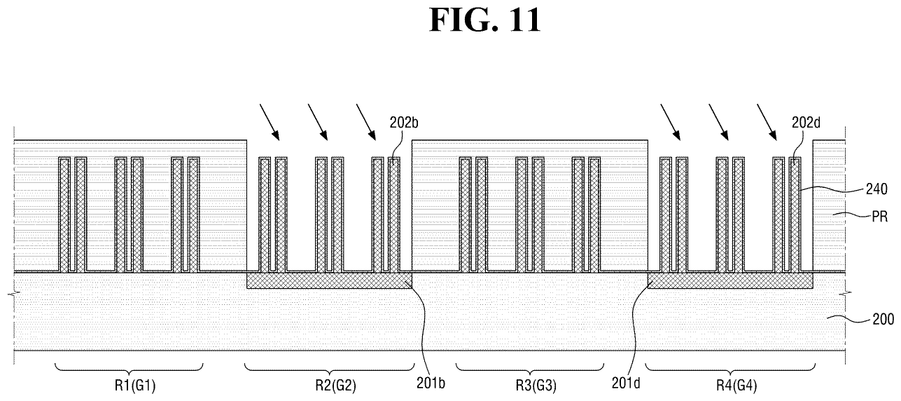

FIG. 11 is a diagram for explaining the step S200 of FIG. 7.

Referring to FIGS. 7 and 11, the first doping process may be performed for a second group G2 and a fourth group G4 of the nanotube array 202 (S200). In addition, the first doping process may be performed for a second region R2 and a fourth region R4 of the substrate 200.

The first doping process may be a process of doping using a p-type doping material.

The substrate 200 may include a first region R1, a second region R2, a third region R3, and a fourth region R4. The second region R2 may be a region between the first region R1 and the third region R3. The third region R3 may be a region between the second region R2 and the fourth region R4.

The first region R1 of the substrate 200 may include a plurality of nanotubes of a first group G1 of the nanotube array 202. The second region R2 of the substrate 200 may include a plurality of nanotubes of a second group G2 of the nanotube array 202. The third region R3 of the substrate 200 may include a plurality of nanotubes of a third group G3 of the nanotube array 202. The fourth region R4 of the substrate 200 may include a plurality of nanotubes of a fourth group G4 of the nanotube array 202.

To perform the first doping process, a protective layer 240 may first be formed on the substrate 200 on which the nanotube array 202 is formed, so as to cover an upper surface of the substrate 200 and the nanotube array 202. The protective layer 240 may be formed on an upper surface of the substrate 200, an upper surface of the nanotube array 202, and sidewalls of the nanotube array 202. The protective layer 240 may be formed before performing the doping process in order to prevent physical damage caused by ion implantation and to block impurities injected during a heat treatment process from escaping to the outside. The protective layer 240 may include an oxide such as SiO₂, SiN, Al₂ O₃, or HfO₂.

A photoresist layer PR may be formed on the protective layer 240. The photoresist layer PR may be formed to cover the upper surface of the substrate 200 and the nanotube array 202. The photoresist layer PR may be selectively removed so that only the second region R2 and the fourth region R4 of the substrate 200 are exposed.

The photoresist layer PR is described as an example, but the present disclosure is not limited thereto. For example, a layer including an oxide may be used, and in this case, an additional etching process may be required to remove the layer.

The p-type doping material for the first doping process may be implanted into the second region R2 and the fourth region R4 of the substrate 200 exposed by the photoresist layer PR. Due to the first doping process, the nanotube array of the second group G2 may become the first p-type nanotube array 202b, and the nanotube array of the fourth group G4 may become the second p-type nanotube array 202d. In addition, due to the first doping process, a first p-type doping region 201b may be formed in a partial region of the second region R2 of the substrate 200, and a second p-type doping region 201d may be formed in a partial region of the fourth region R4 of the substrate 200. After the first doping process is performed, the photoresist layer PR used in the first doping process may be removed.

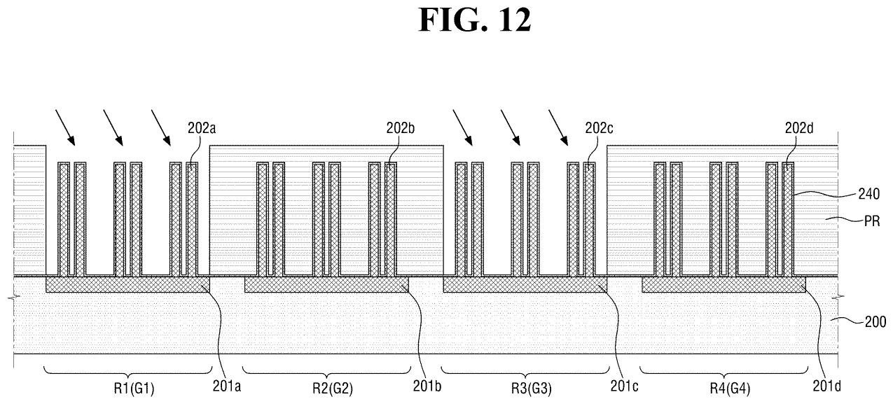

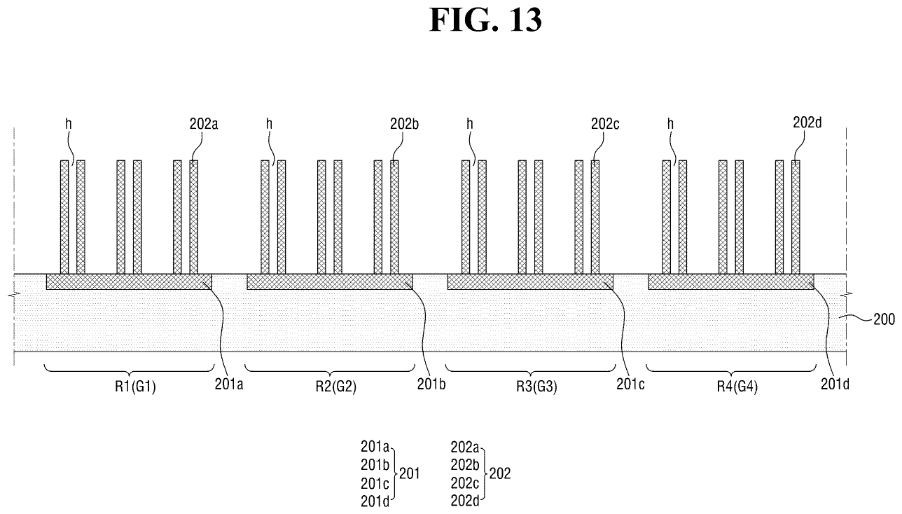

FIGS. 12 and 13 are diagrams for explaining the step S300 of FIG. 7.

Referring to FIGS. 7, 12, and 13, the second doping process may be performed for the first group G1 and the third group G3 of the nanotube array 202 (S300). In addition, the second doping process may be performed for the first region R1 and the third region R3 of the substrate 200.

The second doping process may be a process of doping using an n-type doping material.

The photoresist layer PR may be formed to cover the upper surface of the substrate 200 and the nanotube array 202. The photoresist layer PR may be selectively removed so that only the first region R1 and the third region R3 of the substrate 200 are exposed.

The n-type doping material for the second doping process may be implanted into the first region R1 and the third region R3 of the substrate 200 exposed by the photoresist layer PR. Due to the second doping process, the nanotube array of the first group G1 may become the first n-type nanotube array 202a, and the nanotube array of the third group G3 may become the second n-type nanotube array 202c. In addition, due to the second doping process, a first n-type doping region 201a may be formed in a partial region of the first region R1 of the substrate 200, and a second n-type doping region 201c may be formed in a partial region of the third region R3 of the substrate 200. After the second doping process is performed, the photoresist layer PR used in the second doping process may be removed.

Due to the first doping process and the second doping process, the nanotube array 202 may be doped so that the first n-type nanotube array 202a, the first p-type nanotube array 202b, the second n-type nanotube array 202c, and the second p-type nanotube array 202d may be respectively formed. In addition, due to the first doping process and the second doping process, partial regions including an upper surface of the substrate 200 may be doped so that the first n-type doping region 201a, the first p-type doping region 201b, the second n-type doping region 201c, and the second p-type doping region 201d, which are spaced apart from one another, may be formed in the substrate 200.

After the first and second doping processes are performed, a heat treatment process may be performed to uniformly diffuse doping materials in the doped nanotube array 202 and the doping region 201. After the heat treatment process, the protective layer 240 may be removed.

Referring again to FIG. 7, the method of manufacturing a thermoelectric device comprising a nanotube array according to an embodiment of the present disclosure may include a step S400 of forming a silicide layer after the first and second doping processes are performed.

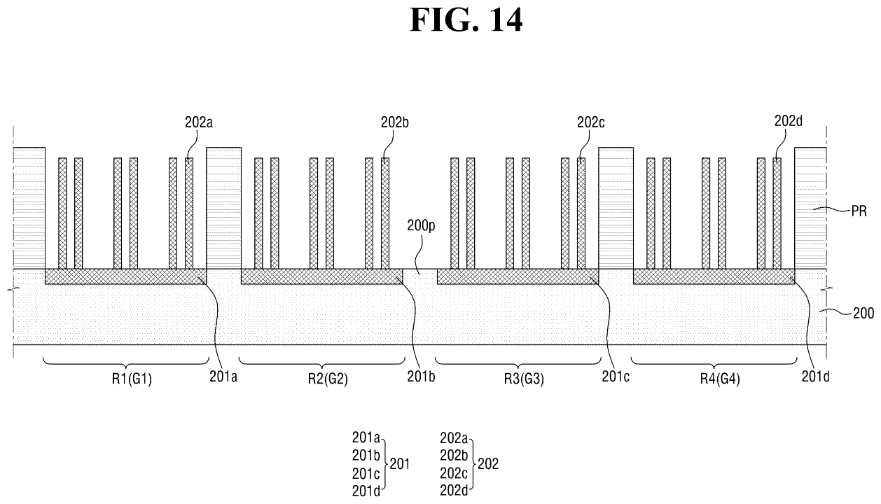

FIGS. 14, 15, and 16 are diagrams for explaining the step S400 of FIG. 7.

Referring to FIGS. 7 and 14, after the first and second doping processes are performed on the nanotube array 202 and the substrate 200, a photoresist layer PR may be formed on the substrate 200 so as to cover the nanotube array 202. The photoresist layer PR may be selectively removed so that the nanotube array 202 and a connection region 200p are exposed.

The photoresist layer PR may not expose a portion of the substrate 200 between the first n-type doping region 201a and the first p-type doping region 201b. In addition, the photoresist layer PR may not expose a portion of the substrate 200 between the second n-type doping region 201c and the second p-type doping region 201d. The photoresist layer PR may expose a connection region 200p, which is a portion of the substrate 200 between the first p-type doping region 201b and the second n-type doping region 201c.

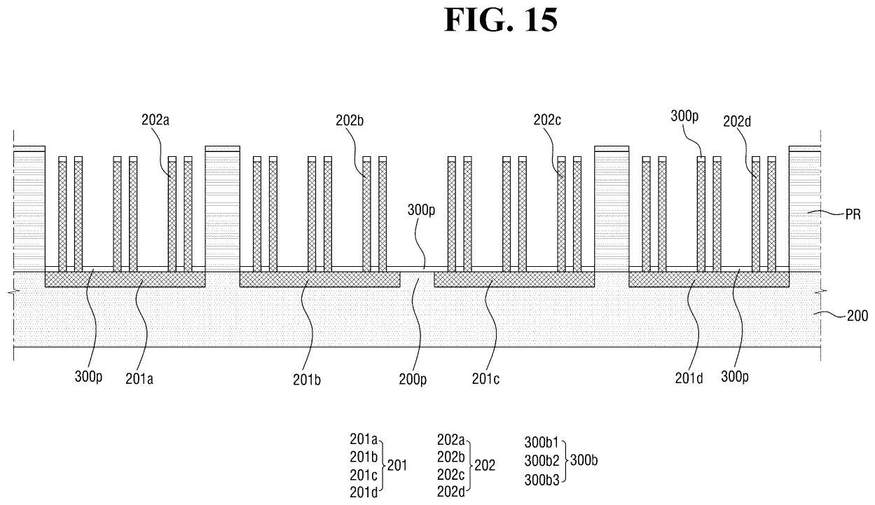

Referring to FIGS. 7 and 15, a metal material layer 300p may be formed. The metal material layer 300p may be formed on the photoresist layer PR and on the nanotube array 202. In addition, the metal material layer 300p may be formed on a portion of the substrate 200 that is exposed due to the hole h of the nanotube array 202. In addition, the metal material layer 300p may be formed on the doping region 201. In addition, the metal material layer 300p may be formed on the connection region 200p.

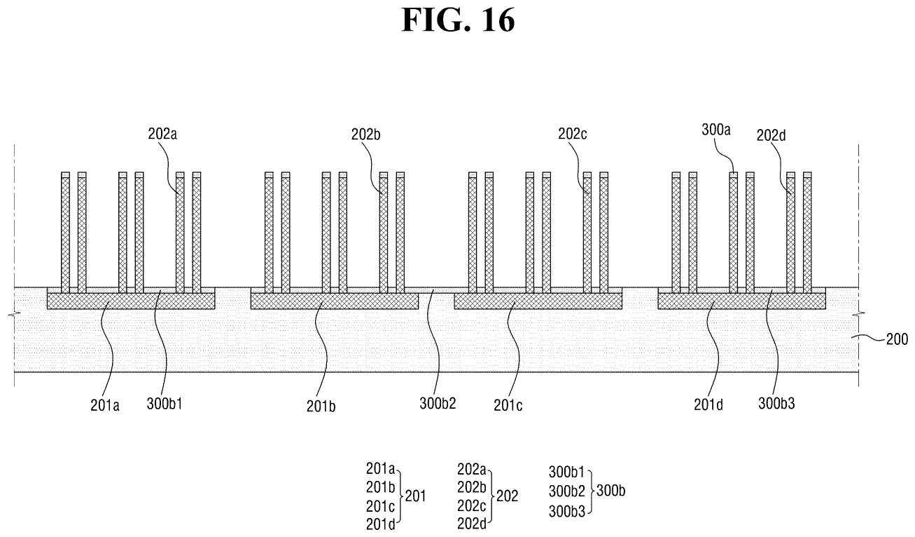

Referring to FIGS. 7 and 16, through heat treatment, the metal material included in the metal material layer 300p may react with silicon included in the substrate 200, so that an upper silicide layer 300a and a lower silicide layer 300b may be formed. Residual metal material and the photoresist layer PR, except for the silicide, may be removed. Due to the second lower silicide layer 300b2, the first p-type nanotube array 202b and the second n-type nanotube array 202c may be electrically connected in series.

Referring again to FIG. 7, the method of manufacturing a thermoelectric device comprising a nanotube array according to an embodiment of the present disclosure may include a step S500 of forming a filling layer 400.

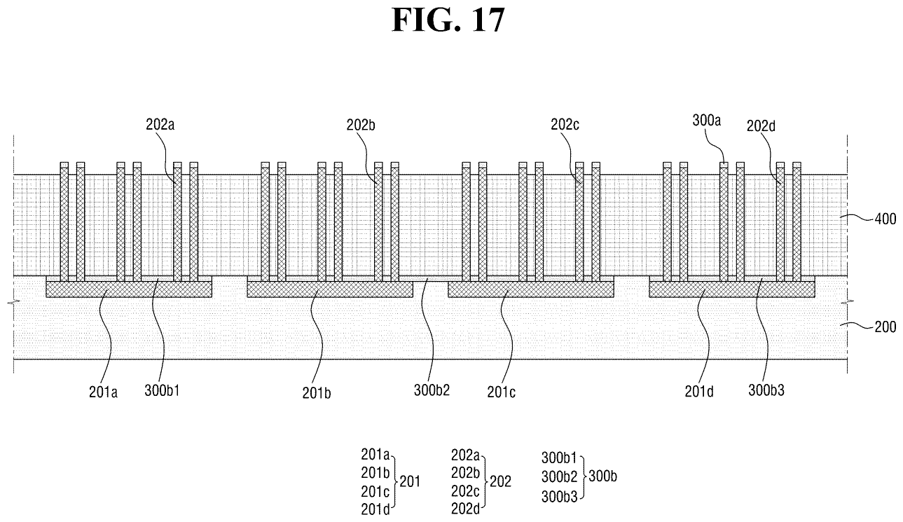

FIG. 17 is a diagram for explaining the step S500 of FIG. 7.

Referring to FIGS. 7 and 17, a filling layer 400 may be formed to fill spaces between the respective nanotube arrays 202 and to expose at least a portion of an upper portion of the nanotube array 202 and the upper silicide layer 300a.

Referring again to FIG. 7, the method of manufacturing a thermoelectric device comprising a nanotube array according to an embodiment of the present disclosure may include a step S600 of forming a first upper electrode and a second upper electrode.

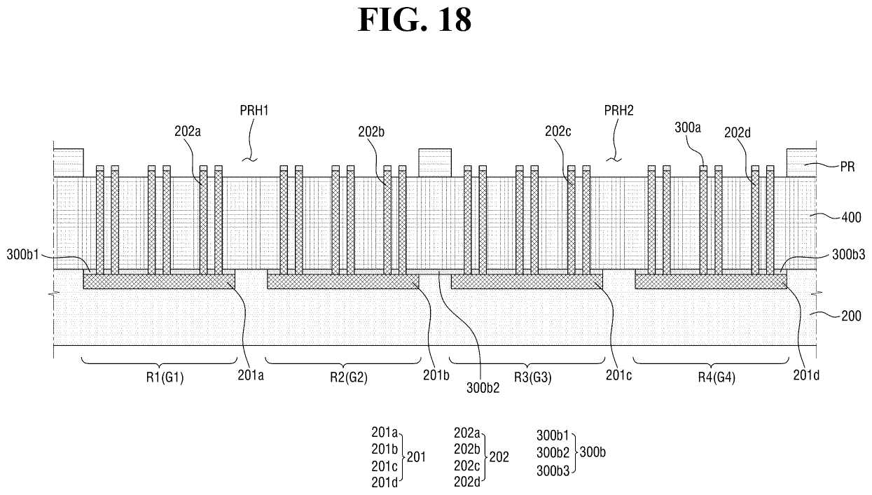

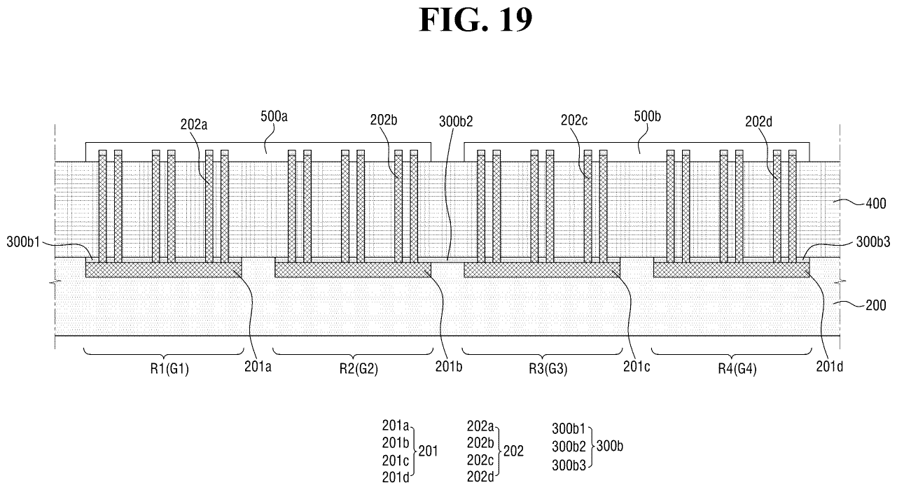

FIGS. 18 and 19 are diagrams for explaining the step S600 of FIG. 7.

Referring to FIGS. 7, 18, and 19, a photoresist layer PR may be formed on the filling layer 400. The photoresist layer PR may include a first recess PRH1 and a second recess PRH2.

The first recess PRH1 may expose an upper portion of the first n-type nanotube array 202a, an upper portion of the first p-type nanotube array 202b, and a portion of the upper silicide layer 300a. In addition, the first recess PRH1 may expose a portion of the filling layer 400 between the upper portion of the first n-type nanotube array 202a and the upper portion of the first p-type nanotube array 202b. The second recess PRH2 may expose an upper portion of the second n-type nanotube array 202c, an upper portion of the second p-type nanotube array 202d, and a remaining portion of the upper silicide layer 300a. In addition, the second recess PRH2 may expose another portion of the filling layer 400 between the upper portion of the second n-type nanotube array 202c and the upper portion of the second p-type nanotube array 202d.

A pattern of the photoresist layer PR may be formed between the first recess PRH1 and the second recess PRH2. For example, a portion of the photoresist layer PR in the form of a pattern may be formed between the upper portion of the first p-type nanotube array 202b and the upper portion of the second n-type nanotube array 202c, which are exposed by the filling layer 400.

Based on the photoresist layer PR including the first recess PRH1 and the second recess PRH2, a metal material may be deposited, so that the first upper electrode 500a and the second upper electrode 500b may be formed.

A method of forming the upper electrodes is not limited thereto. For example, the first upper electrode 500a and the second upper electrode 500b may be formed through an etching process. For example, it is also possible that the first upper electrode 500a and the second upper electrode 500b are formed by sequentially depositing a metal material layer, a hard mask layer, and a photoresist layer on the filling layer 400, and then patterning the three layers.

Referring again to FIG. 7, the method of manufacturing a thermoelectric device comprising a nanotube array according to an embodiment of the present disclosure may include a step S700 of forming an insulating layer.

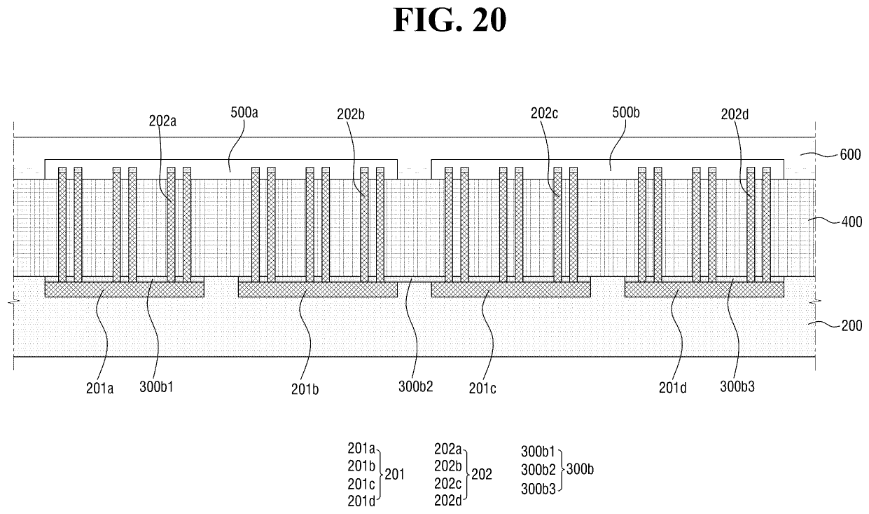

FIG. 20 is a diagram for explaining the step S700 of FIG. 7.

Referring to FIGS. 7 and 20, an insulating layer 600 may be formed on the first upper electrode 500a, the second upper electrode 500b, and the filling layer 400. The insulating layer 600 may be formed to cover the first upper electrode 500a and the second upper electrode 500b.

Referring again to FIG. 7, the method of manufacturing a thermoelectric device comprising a nanotube array according to an embodiment of the present disclosure may include a step S800 of forming a heat dissipation part. Referring also to FIG. 2, the heat dissipation part 100 may be formed on each of an upper portion and a lower portion of the substrate 200.

The method of manufacturing a thermoelectric device comprising a nanotube array according to an embodiment of the present disclosure is capable of being manufactured by using processes and equipment used in the manufacturing of conventional semiconductor devices, without separate processes or facilities, thereby enabling mass production and being cost-effective.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A thermoelectric device comprising a nanotube array, the thermoelectric device comprising:
a substrate;
a doping region in the substrate, the doping region comprising a first n-type doping region, a second n-type doping region, a first p-type doping region, and a second p-type doping region, which are arranged to be spaced apart from one another;
a nanotube array comprising a first n-type nanotube array, a second n-type nanotube array, a first p-type nanotube array, and a second p-type nanotube array, each of which is arranged on a corresponding one of the first n-type doping region, the second n-type doping region, the first p-type doping region, and the second p-type doping region, wherein each of the first n-type nanotube array, the second n-type nanotube array, the first p-type nanotube array, and the second p-type nanotube array comprises a hole therein;
a first upper electrode electrically connecting an upper portion of the first n-type nanotube array and an upper portion of the first p-type nanotube array;
a second upper electrode electrically connecting an upper portion of the second n-type nanotube array and an upper portion of the second p-type nanotube array; and
a heat dissipation part arranged on an upper portion of the substrate and a lower portion of the substrate,
wherein each of the nanotube arrays has a wall thickness of greater than or equal to 30 nm and less than or equal to 999 nm.

2. The thermoelectric device comprising a nanotube array according to claim 1,
wherein a doping concentration of each of the nanotube arrays is greater than or equal to 10¹⁹ cm⁻³ and less than or equal to 10²¹ cm⁻³.

3. The thermoelectric device comprising a nanotube array according to claim 1,
wherein the first p-type doping region is arranged between the first n-type doping region and the second n-type doping region, and
the second n-type doping region is arranged between the first p-type doping region and the second p-type doping region.

4. The thermoelectric device comprising a nanotube array according to claim 3, further comprising:
an upper silicide layer arranged on each of the nanotube arrays; and
a lower silicide layer arranged under each of the nanotube arrays,
wherein the lower silicide layer comprises:
a first lower silicide layer arranged on the first n-type doping region and arranged on a portion of the substrate exposed by the hole of the first n-type nanotube array;
a second lower silicide layer arranged on the first p-type doping region, on the second n-type doping region, on a portion of the substrate exposed by the hole of the first p-type nanotube array, on a portion of the substrate exposed by the hole of the second n-type nanotube array, and on another portion of the substrate between the first p-type doping region and the second n-type doping region; and
a third lower silicide layer arranged on the second p-type doping region and arranged on a portion of the substrate exposed by the hole of the second p-type nanotube array.

5. The thermoelectric device comprising a nanotube array according to claim 1,
wherein each of the nanotube arrays comprises the same material as the substrate.

6. The thermoelectric device comprising a nanotube array according to claim 1,
wherein the nanotube arrays are arranged to be spaced apart from one another,
and further comprising a filling layer that fills spaces between the respective nanotube arrays.

7. The thermoelectric device comprising a nanotube array according to claim 1,
wherein each of the nanotubes of the nanotube array is in any one of the following forms: a form in which the repetition of diameter increase and decrease from top to bottom is constant in magnitude of the diameter, a form in which the repetition of diameter increase and decrease from top to bottom gradually increases in magnitude of the diameter, a form in which the repetition of diameter increase and decrease from top to bottom gradually decreases in magnitude of the diameter, an hourglass shape in which the repetition of diameter increase and decrease from top to bottom gradually decreases and then increases in magnitude of the diameter so that a central portion is concave, or a bulging shape in which the repetition of diameter increase and decrease from top to bottom gradually increases and then decreases in magnitude of the diameter so that a central portion is convex.

8. The thermoelectric device comprising a nanotube array according to claim 1,
wherein a horizontal cross-section of each of nanotubes of the nanotube array is any one of a circle and a polygon, the circle and the polygon including the hole.

9. The thermoelectric device comprising a nanotube array according to claim 1,
wherein a doping material for n-type doping of the n-type of the doping region and the n-type of the nanotube array includes an atom having five valence electrons, and
a doping material for p-type doping of the p-type of the doping region and the p-type of the nanotube array includes an atom having three valence electrons.

10. The thermoelectric device comprising a nanotube array according to claim 1,
wherein each of the first upper electrode, the second upper electrode, and the heat dissipation part includes at least one material selected from the group consisting of Pt, Al, Au, Cu, W, Ti, and Cr.

11. A method of manufacturing a thermoelectric device comprising a nanotube array, the method comprising:
patterning a ring mask pattern on a substrate;
forming the nanotube array by removing a portion of the substrate using a dry etching process based on the ring mask pattern, the nanotube array having a hole therein and a wall thickness;
performing a first doping process by performing a p-type doping process on a first group comprised in a first region of the substrate and a second group comprised in a second region of the substrate, and on portions of the first region and the second region of the substrate among the nanotube array, to form a first p-type doping region in the first region, to form a second p-type doping region in the second region, to form the first group as a first p-type nanotube array, and to form the second group as a second p-type nanotube array;
performing a second doping process by performing an n-type doping process on a third group comprised in a third region of the substrate and a fourth group included in a fourth region of the substrate, and on portions of the third region and the fourth region of the substrate among the nanotube array, to form a first n-type doping region in the third region, to form a second n-type doping region in the fourth region, to form the third group as a first n-type nanotube array, and to form the fourth group as a second n-type nanotube array;
forming a first upper electrode electrically connecting an upper portion of the first n-type nanotube array and an upper portion of the first p-type nanotube array;
forming a second upper electrode electrically connecting an upper portion of the second n-type nanotube array and an upper portion of the second p-type nanotube array; and
forming a heat dissipation part on a lower portion and an upper portion of the substrate,
wherein the wall thickness is greater than or equal to 30 nm and less than or equal to 999 nm.

12. The method of manufacturing a thermoelectric device comprising a nanotube array according to claim 11,
wherein a doping concentration of each of the first doping process and the second doping process is greater than or equal to 10¹⁹ cm⁻³ and less than or equal to 10²¹ cm⁻³.

13. The method of manufacturing a thermoelectric device comprising a nanotube array according to claim 11,
wherein the first p-type doping region is arranged between the first n-type doping region and the second n-type doping region, and
the second n-type doping region is arranged between the first p-type doping region and the second p-type doping region.

14. The method of manufacturing a thermoelectric device comprising a nanotube array according to claim 13, the method comprising:
forming an upper silicide layer on each of the nanotube arrays;
forming a first lower silicide layer arranged on the first n-type doping region and arranged on a portion of the substrate exposed by the hole of the first n-type nanotube array;
forming a second lower silicide layer arranged on the first p-type doping region, the second n-type doping region, a portion of the substrate exposed by the hole of the first p-type nanotube array, and a portion of the substrate exposed by the hole of the second n-type nanotube array, and further arranged on another portion of the substrate between the first p-type doping region and the second n-type doping region; and
forming a third lower silicide layer arranged on the second p-type doping region and arranged on a portion of the substrate exposed by the hole of the second p-type nanotube array.

15. The method of manufacturing a thermoelectric device comprising a nanotube array according to claim 14, further comprising:
before forming the first upper electrode and the second upper electrode,
forming a filling layer that fills spaces between the respective nanotube arrays and exposes at least a portion of the upper silicide layer and an upper portion of each of the nanotube arrays.

16. A method of manufacturing a thermoelectric device comprising a nanotube array, the method comprising:
patterning a plurality of ring mask patterns spaced apart from one another on a substrate, each of the plurality of ring mask patterns comprising a pre-hole exposing a portion of an upper surface of the substrate;
forming a pre-catalyst layer on the substrate and the plurality of ring mask patterns;
forming a catalyst layer by removing the plurality of ring mask patterns to expose partial regions of the substrate corresponding to the plurality of ring mask patterns;
forming the nanotube array having a hole therein and a wall thickness by removing a portion of the substrate using a wet etching process based on the catalyst layer;
performing a first doping process by performing a p-type doping process on a first group included in a first region of the substrate and a second group included in a second region of the substrate, and on portions of the first region and the second region of the substrate among the nanotube array, to form a first p-type doping region in the first region, to form a second p-type doping region in the second region, to form the first group as a first p-type nanotube array, and to form the second group as a second p-type nanotube array;
performing a second doping process by performing an n-type doping process on a third group included in a third region of the substrate and a fourth group included in a fourth region of the substrate, and on portions of the third region and the fourth region of the substrate among the nanotube array, to form a first n-type doping region in the third region, to form a second n-type doping region in the fourth region, to form the third group as a first n-type nanotube array, and to form the fourth group as a second n-type nanotube array;
forming a first upper electrode electrically connecting an upper portion of the first n-type nanotube array and an upper portion of the first p-type nanotube array;
forming a second upper electrode electrically connecting an upper portion of the second n-type nanotube array and an upper portion of the second p-type nanotube array; and
forming a heat dissipation part on a lower portion and an upper portion of the substrate,
wherein the wall thickness is greater than or equal to 30 nm and less than or equal to 999 nm.

17. The method of manufacturing a thermoelectric device comprising a nanotube array according to claim 16,
wherein a doping concentration of each of the first doping process and the second doping process is greater than or equal to 10¹⁹ cm⁻³ and less than or equal to 10²¹ cm⁻³.

18. The method of manufacturing a thermoelectric device comprising a nanotube array according to claim 16,
wherein the first p-type doping region is arranged between the first n-type doping region and the second n-type doping region, and
the second n-type doping region is arranged between the first p-type doping region and the second p-type doping region.

19. The method of manufacturing a thermoelectric device comprising a nanotube array according to claim 18, the method further comprising:
forming an upper silicide layer on each of the nanotube arrays;
forming a first lower silicide layer arranged on the first n-type doping region and arranged on a portion of the substrate exposed by the hole of the first n-type nanotube array;
forming a second lower silicide layer arranged on the first p-type doping region, the second n-type doping region, a portion of the substrate exposed by the hole of the first p-type nanotube array, and a portion of the substrate exposed by the hole of the second n-type nanotube array, and further arranged on another portion of the substrate between the first p-type doping region and the second n-type doping region; and
forming a third lower silicide layer arranged on the second p-type doping region and arranged on a portion of the substrate exposed by the hole of the second p-type nanotube array.

20. The method of manufacturing a thermoelectric device comprising a nanotube array according to claim 19, further comprising:
before forming the first upper electrode and the second upper electrode,
forming a filling layer that fills spaces between the respective nanotube arrays and exposes at least a portion of the upper silicide layer and an upper portion of each of the nanotube arrays.
